(19) United States
(12) Patent Application Publication
(10) Pub. No.: US 2025/0233026 A1
(43) Pub. Date: Jul. 17, 2025

(54) SEMICONDUCTOR DEVICE AND METHOD FOR FABRICATING THE SAME

(71) Applicant: TAIWAN SEMICONDUCTOR MANUFACTURING COMPANY, LTD., Hsinchu (TW)

(72) Inventors: Chi-Hui LAI, Taichung City (TW); Ming Jun LI, New Taipei City (TW); Yang-Che CHEN, Hsinchu City (TW); Hsiang-Tai LU, Hsinchu County (TW); Wei-Ray LIN, Hsinchu City (TW)

(73) Assignee: TAIWAN SEMICONDUCTOR MANUFACTURING COMPANY, LTD., Hsinchu (TW)

(21) Appl. No.: 18/410,133

(22) Filed: Jan. 11, 2024

(51) Int. Cl. H01L 21/66; H01L 21/768; H01L 23/522

(52) U.S. Cl. CPC H01L 22/14; H01L 21/768; H01L 22/30; H01L 23/5226

(57) ABSTRACT

A method for fabricating a semiconductor device is provided. The method includes forming a transistor over a semiconductor substrate; forming an interconnect structure including a test structure; forming conductive pads respectively electrically connected with nodes of the test structure, and performing a probe test on the conductive pads. A tower of the test structure connected between the two nodes includes at least one test metal via of a first via layer, at least one test metal via of a second via layer, and at least one test metal via of a third via layer. A size of the test metal via of the second via layer is less than a size of the test metal via of the third via layer, and a number of the test metal via of the second via layer is less than a number of the test metal via of the first via layer.

### BACKGROUND

Semiconductor chips are small electronic devices that are used in a wide range of applications such as personal computers, cellular telephones, and gaming devices. Each chip is actually a small piece of semiconductor material onto which have been fabricated a large number of integrated circuits. Each integrated circuit, in turn, includes a number of tiny electronic components that are interconnected together. A semiconductor is a material that when properly prepared is capable of conducting electricity under certain controllable conditions, such as the application of the small electrical charge. Each of the small components in an integrated circuit is fabricated using successive layers of semiconductor, insulating, and conducting materials arranged in a certain fashion. Sometimes, due to fabrication process variations, electrostatic over stress (EOS) may occur and cause damage to integrated circuits.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a top view of a test structure according to some embodiments of the present disclosure.

FIG. 1B is a cross-sectional view of the test structure of FIG. 1A.

FIG. 2A is a top view of a test structure according to some embodiments of the present disclosure.

FIG. 2B is a cross-sectional view of the test structure of FIG. 2A.

FIG. 3 is a flow chart of a method for fabricating a package structure according to some embodiments of the present disclosure.

FIGS. 4A-10 are schematic views illustrating the method for fabricating the package structure according to some embodiments of the present disclosure.

FIG. 11A is a cross-sectional view illustrating a test structure with burn-out according to some embodiments of the present disclosure.

FIG. 11B is an enlarged view of a portion of FIG. 11A.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

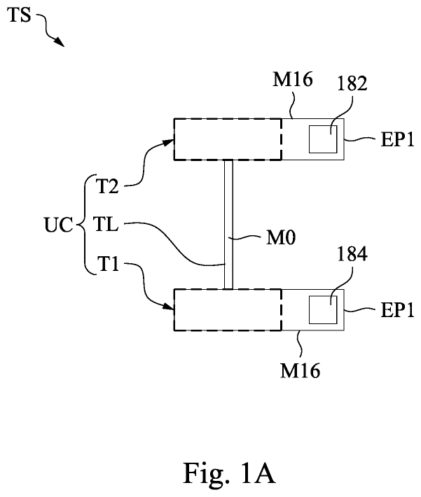

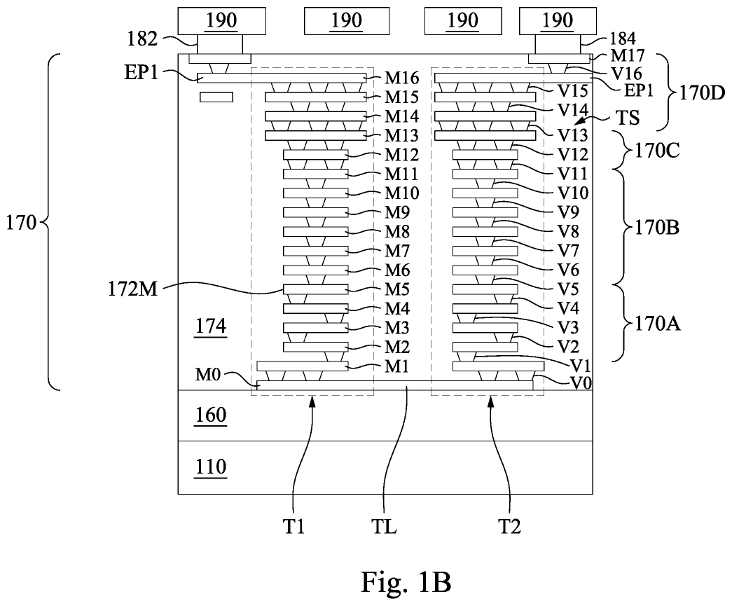

FIG. 1A is a top view of a test structure TS according to some embodiments of the present disclosure. FIG. 1B is a cross-sectional view of the test structure TS of FIG. 1A. A semiconductor substrate 110 is provided. The semiconductor substrate 100 may be a bulk silicon substrate. Alternatively, the semiconductor substrate 100 may include an elementary semiconductor, such as silicon (Si) or germanium (Ge) in a crystalline structure; a compound semiconductor, such as silicon germanium (SiGe), silicon carbide (SiC), gallium arsenic (GaAs), gallium phosphide (GaP), indium phosphide (InP), indium arsenide (InAs), and/or indium antimonide (InSb); or combinations thereof. Possible semiconductor substrate 100 also include a silicon-on-insulator (SOI) substrate. SOI substrates are fabricated using separation by implantation of oxygen (SIMOX), wafer bonding, and/or other suitable methods.

In semiconductor technology, the semiconductor substrate 110 is processed through various fabrication steps to form integrated circuits (ICs). The fabrication steps may include a front-end-of-line (FEOL) process, a middle-end-of-line (MEOL) process, and a back-end-of-line (BEOL) process. The FEOL process and the MEOL process may include forming transistors, capacitors, diodes, and/or resistors on a semiconductor substrate. For example, the FEOL process may form a FEOL structure 160 over the semiconductor substrate 110. The back end of the line includes forming metal layer interconnects and vias to provide routing for components at the front end of the line. The test structure TS is formed during the fabrication of many layers containing circuitry including the BEOL processing. For example, the BEOL process may form a BEOL structure 170 including the test structure TS over the semiconductor substrate 110.

The BEOL structure 170 includes plural stacked metallization layers and via layers embedded in the one or more dielectric layers 174. In some embodiments, the plural metallization layers include a top-most metal layer M17, a bottom-most metal layer M0, and other metal layers M1-M16 therebetween. Each metallization layer may include one or more metal lines 172M. Vertical columnar vias V0-V16 interconnect every two adjacent metal layers M0-M17. The metal layers M0-M17 and the vertical columnar vias V0-V16 may be made of copper or other suitable conductive material.

In the context, the BEOL structure 170 may also be referred to as multi-level interconnect structure.

The plural stacked metal features and via layers in the BEOL structure 170 form the test structure TS. In some embodiments of the present disclosure, the test structure TS includes one or more unit cells UC, each unit cell UC includes a tower T1, a tower T2, and a connection line TL connecting the tower T1 to the tower T2. The towers T1 and T2 are respectively indicated as dashed blocks. Each of the towers T1 and T2 includes plural metal lines 172M in the metal layers (e.g., the metal layers M0-M16) and the vertical columnar vias (e.g., the vias V0-V15) interconnecting every two adjacent metal layers (e.g., the metal layers M0-M16). The connection line TL is a metal line 172M of a metal layer at the same level as the bottommost metal layer (e.g., the metal layer M0) of the towers T1 and T2.

First and second test contact pads 182 and 184 are formed over the BEOL structure 170. The first and second test contact pads 182 and 184 may be made of aluminum or other suitable conductive material. In some embodiments, die connectors 190 are formed over the test contact pads 182 and 184 for electrical connection with other structures. In the context, the die connectors may also be referred to as conductive pads.

The test structure TS may establish a conductive path from the first test contact pad 182 to the second test contact pad 184. For example, first and second test contact pads 182 and 184 are over and in contact with the metal lines 172M of the metal layer (e.g., the metal layer M17) higher than the topmost metal layer (e.g., the metal layer M16) of the tower T1/T2. In the present embodiments where a single unit cell UC connecting the first test contact pad 182 to the second test contact pad 184, the topmost metal layer (e.g., the metal layer M16) of the tower T1/T2 may have an extension portion EP1 overlapping the metal lines 172M of the metal layer (e.g., the metal layer M17) that is in contact with the first and second test contact pads 182 and 184. And, vertical columnar vias V16 may interconnect the extension portion EP1 of the topmost metal layer (e.g., the metal layer M16) of the tower T1/T2 to the metal lines 172M of the metal layer (e.g., the metal layer M17) that is in contact with the first and second test contact pads 182 and 184.

The BEOL structure 170 may include four sections 170A, 170B, 170C, and 170D. For example, the metal layers M2-M5 and the vertical columnar vias V1-V4 are of the section 170A, the metal layers M6-M11 and the vertical columnar vias V5-V10 are of the section 170B, the metal layers M12-M13 and the vertical columnar vias V11-V12 are of the section 170C, and the metal layers M14-M17 and the vertical columnar vias V13-V16 are of the section 170D. In some embodiments, the metallization layers and via layers in these four sections 170A, 170B, 170C, and 170D may be arranged under different design rules and schemes. Therefore, the metallization layers and via layers in these four sections 170A, 170B, 170C, and 170D may have different configurations, such as different line widths, different line height/thickness, different via sizes (e.g., different via height and/or different via width), the like, or the combination thereof. The configurations of the vertical columnar vias V0 may be the same as some of the vertical columnar vias V1-V4 (e.g., the vertical columnar vias V1, V2) and different from the others of the vertical columnar vias V1-V4 (e.g., the vertical columnar vias V3, V4).

For example, in FIG. 1B, top via widths of the vertical columnar vias V13-V16 of the section 170D are greater than top via widths of the vertical columnar vias V11-V12 of the section 170C, top via widths of the vertical columnar vias V11-V12 of the section 170C are greater than top via widths of the vertical columnar vias V5-V10 of the section 170B, and the top via widths of the vertical columnar vias V5-V10 of the section 170B are greater than top via widths of the vertical columnar vias V1-V4 of the section 170A. And, in FIG. 1B, bottom via widths of the vertical columnar vias V13-V16 of the section 170D are greater than bottom via widths of the vertical columnar vias V11-V12 of the section 170C, bottom via widths of the vertical columnar vias V11-V12 of the section 170C are greater than bottom via widths of the vertical columnar vias V5-V10 of the section 170B, and the bottom via widths of the vertical columnar vias V5-V10 of the section 170B are greater than bottom via widths of the vertical columnar vias V1-V4 of the section 170A. In the context, the top via widths are referred to as a width of a top side of the vias adjoining an overlying metal layer. And, the bottom via widths are referred to as a width of a bottom side of the vias adjoining an underlying metal layer.

For example, the bottom via widths of the vertical columnar vias V13-V16 of the section 170D may be in a range from about 100 nanometers to about 500 nanometers. The bottom via widths of the vertical columnar vias V11-V12 of the section 170C may be in a range from about 50 nanometers to about 100 nanometers. The bottom via widths of the vertical columnar vias V5-V10 of the section 170B may be in a range from about 40 nanometers to about 70 nanometers. The bottom via widths of the vertical columnar vias V1-V4 of the section 170A may be in a range from about 5 nanometers to about 30 nanometers.

In some embodiments, at least two of the vertical columnar vias V13-V16 of the same section 170D may have different top/bottom via widths from each other. In some embodiments, at least two of the vertical columnar vias V11-V12 of the same section 170C may have different top/bottom via widths from each other. In some embodiments, at least two of the vertical columnar vias V5-V10 of the same section 170B may have different top/bottom via widths from each other. In some embodiments, at least two of the vertical columnar vias V1-V4 of the same section 170A may have different top/bottom via widths from each other. In some embodiments, a bottom via width of the vertical columnar via V0 may have be the same as that of the vertical columnar vias V1 and V2 but less than a bottom via width of the vertical columnar vias V3 and V4.

In some embodiments, via heights of the vertical columnar vias V13-V16 of the section 170D are greater than via heights of the vertical columnar vias V11-V12 of the section 170C, via heights of the vertical columnar vias V11-V12 of the section 170C are greater than via heights of the vertical columnar vias V5-V10 of the section 170B, and the via heights of the vertical columnar vias V5-V10 of the section 170B are greater than via heights of the vertical columnar vias V1-V4 of the section 170A. In some embodiments, the via heights of the vertical columnar vias V13-V16 of the same section 170D may be the same as that of each other. In some embodiments, the via heights of the vertical columnar vias V11-V12 of the section 170C may be the same as that of each other. In some embodiments, the via heights of the vertical columnar vias V5-V10 of the section 170B may be the same as that of each other. In some embodiments, the via heights of the vertical columnar vias V-V4 of the section 170A may be the same as that of each other. In some embodiments, at least two of the vertical columnar vias V13-V16 of the same section 170D may have different the via heights from each other. In some embodiments, at least two of the vertical columnar vias V11-V12 of the section 170C may have different via heights from each other. In some embodiments, at least two of the vertical columnar vias V5-V10 of the section 170B may have different via heights from each other. In some embodiments, at least two of the vertical columnar vias V1-V4 of the section 170A may have different via heights from each other. In the context, the via heights may be referred to as a vertical distance between two adjacent metal layers.

In some embodiments, height/thicknesses of the metal layers M14-M17 are greater than heights of the metal layers M12-M13, height/thicknesses of the metal layers M12-M13 are greater than heights of the metal layers M6-M11, and the height/thicknesses of the metal layers M6-M11 are greater than heights of the metal layers M2-M5. In some embodiments, the metal layer M0 and M1 may have the same configurations (e.g., the same line widths and or the same line height) as that of the metal layers M2-M5.

In each of the tower T1/T2, the number of the vertical columnar via V11/V12 in the section 170C is greater than the number of vertical columnar via V1/V2/V3/V4/V5/V6/V7/V8/V9/V10 in the sections 170A and 170B. And, in some embodiments, in each of the tower T1/T2, the number of the vertical columnar via V0 is greater than the number of vertical columnar via V1/V2/V3/V4/V5/V6/V7/V8/V9/V10 in the sections 170A and 170B. For example, in the illustrated embodiments, each of the tower T1/T2 includes two vertical columnar vias V0, one vertical columnar via V1, one vertical columnar via V2, one vertical columnar via V3, one vertical columnar via V4, one vertical columnar via V5, one vertical columnar via V6, one vertical columnar via V7, one vertical columnar via V8, one vertical columnar via V9, one vertical columnar via V10, two vertical columnar vias V11, and two vertical columnar vias V12.

In some further embodiments, the number of the vertical columnar vias V13/V14/V15 may be designed according to device requirements. For example, in the illustrated embodiments, each of the tower T1/T2 includes nine vertical columnar vias V13, eight vertical columnar vias V14, and nine vertical columnar vias V15.

During wafer or package process (Integrated Fan-out (InFO), outsourced semiconductor assembly and test (OSAT) flip-chip, and on-substrate process), the large number of generated charges may result in electrostatic over stress (EOS) damage of chip. In some embodiments of the present disclosure, the EOS can be monitored by the test structure TS. In some embodiments of the present disclosure, the vertical columnar vias V1-V4 in the section 170A have minimum via sizes and minimum via numbers (compared to vertical columnar vias V0 and V5-V16), and therefore the electrostatic over stress (EOS) burn out may occur at vertical columnar vias V1-V4 in the section 170A, such as at the vertical columnar vias V2.

In some embodiments, the vertical columnar vias V5-V10 of the section 170B are vertically aligned with each other, and the vertical columnar vias V1-V4 of the section 170A are vertically misaligned with each other. And, the vertical columnar vias V1-V4 of the section 170A may be misaligned from the vertical columnar vias V5-V10 of the section 170B and the vertical columnar vias V0. The misalignment arrangement of the vertical columnar vias V1-V4 may increase an electrical resistance in the section 170A, such that the EOS burn out may occur at vertical columnar vias V1-V4 in the section 170A.

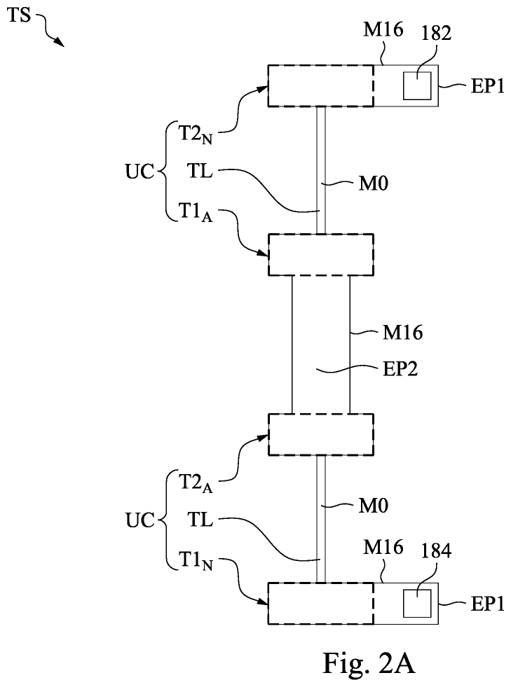

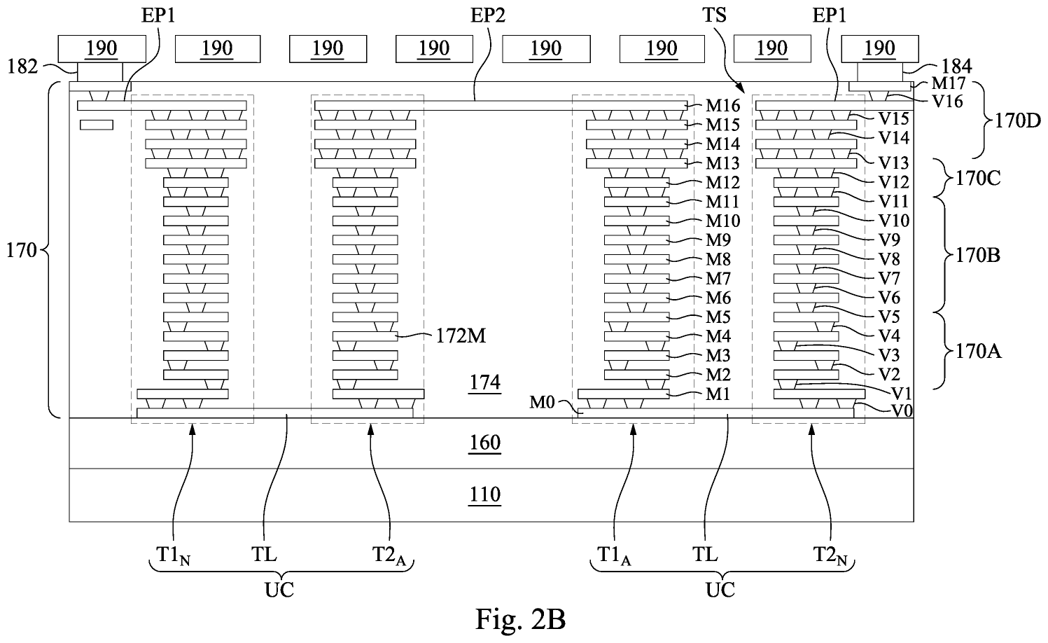

FIG. 2A is a top view of a test structure according to some embodiments of the present disclosure. FIG. 2B is a cross-sectional view of the test structure of FIG. 2A. Details of the present embodiments are similar to those of FIGS. 1A and 1B, except that two or more unit cells UC form a daisy chain from the first test contact pad 182 to the second test contact pad 184. The towers of the unit cells UC are cascade-connected chain from the first test contact pad 182 to the second test contact pad 184. In FIG. 2A, the towers near the first and second test contact pads 182 and 184 are indicated as towers T1_{N} and T2_{N}, while the other towers, which away from the first and second test contact pads 182 and 184, are indicated as towers T1_{A} and T2_{A}.

In the present embodiments, for two towers T1_{A} and T2_{A}, the topmost metal layer (e.g., the metal layer M16) of the tower T1_{A}/T2_{A} may have an extension portion EP1 to receive the vertical columnar vias V16, which may interconnect the extension portion EP1 of the topmost metal layer (e.g., the metal layer M16) of the tower T1_{A}/T2_{A} to the metal lines 172M of the metal layer (e.g., the metal layer M17) that is in contact with the first and second test contact pads 182 and 184. For the towers T1_{A} and T2_{A} away from the first and second test contact pads 182 and 184, the topmost metal layer (e.g., the metal layer M16) of the tower T1_{A}/T2_{A} may have an extension portion EP2 to connect adjacent towers T1_{A} and T2_{A}, thereby allowing the towers T1_{A}/T2_{A} cascade-connected. In the context, the extension portion EP2 may also be referred to as conductive line.

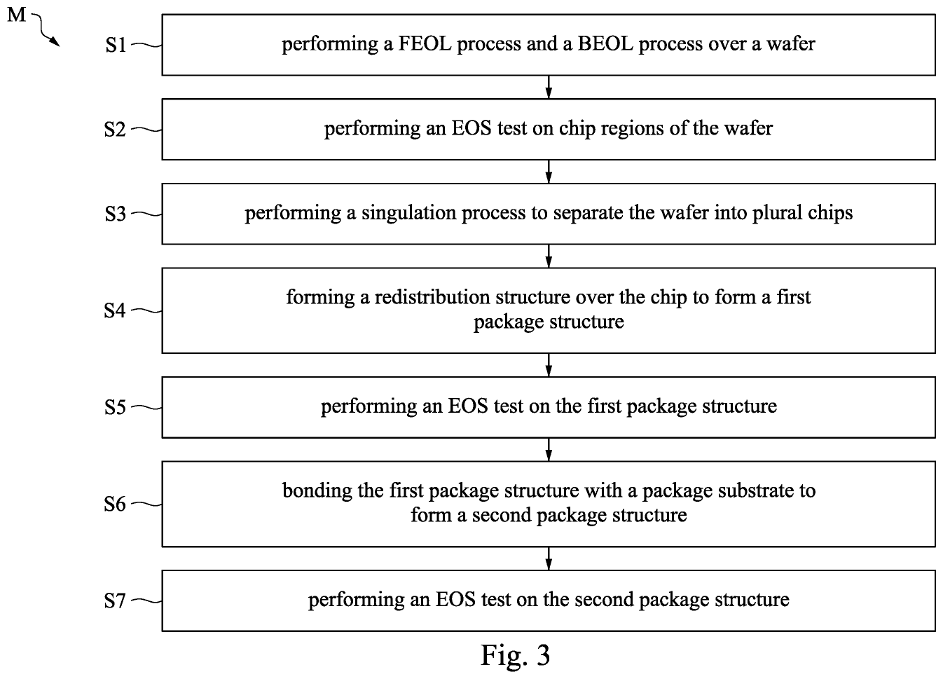

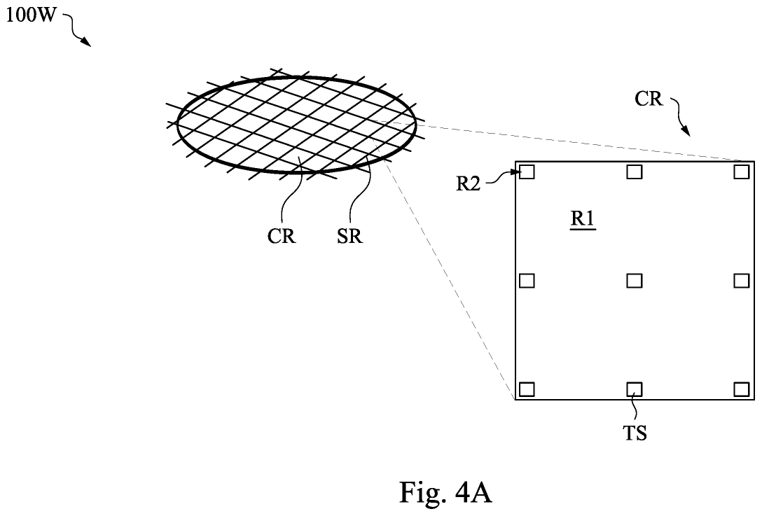

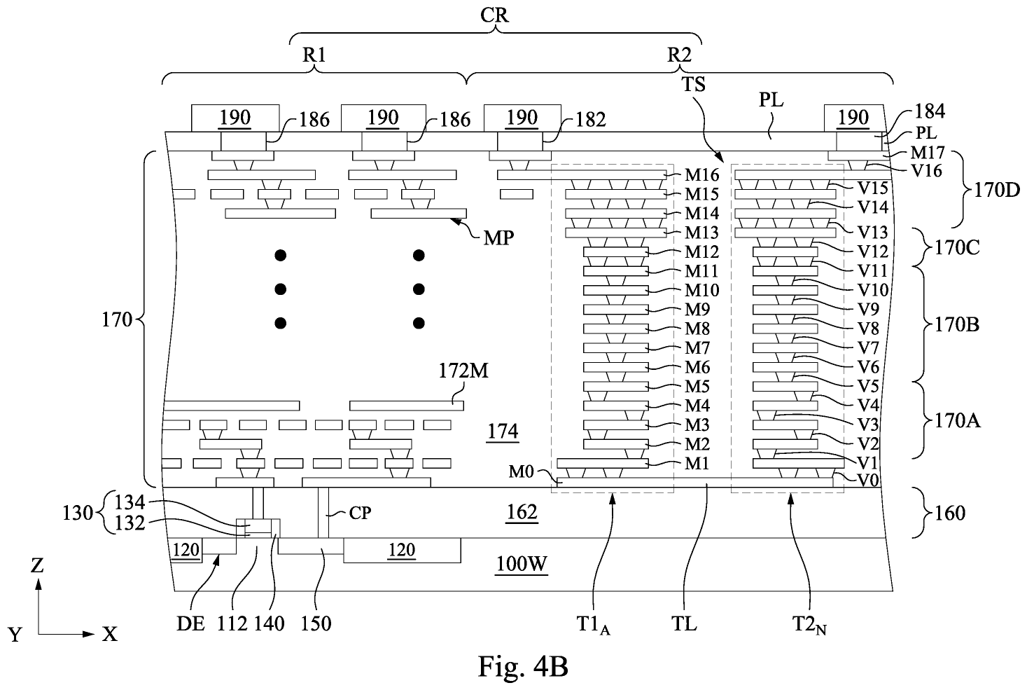

FIG. 3 is a flow chart of a method M for fabricating a package structure according to some embodiments of the present disclosure. FIGS. 4A-10 are schematic views illustrating the method M for fabricating the package structure according to some embodiments of the present disclosure. The method M includes steps S1-S8. At step S1, a FEOL process and a BEOL process are performed over a wafer. At step S2, an EOS test is performed on chip regions of the wafer. At step S3, a singulation process is performed to separate the wafer into plural chips. At step S4, a redistribution structure is formed on a chip to form a first package structure. At step S5, an EOS test is performed on the first package structure. At step S6, the first package structure is bonded with a package substrate to form a second package structure. At step S7, an EOS test is performed on the second package structure. It is understood that additional steps may be provided before, during, and after the steps shown in FIGS. 4A-10, and some of the steps S1-S7 described below can be replaced or eliminated for additional embodiments of the method. The order of the operations/processes may be interchangeable.

Reference is made to FIG. 3 and FIGS. 4A-4B. FIG. 4A is a simplified schematic view of a wafer 100W according to some embodiments of the present disclosure. FIG. 4B is a cross-section view of the wafer 100W. The method M begins at step S1, where a FEOL process and a BEOL process are performed over the wafer 100W. The wafer 100W comprises an array of chip regions CR. In some embodiments, the chip regions CR may be separated from each other by two sets of intersecting scribe line regions SR. The wafer 100W may serve as the aforementioned semiconductor substrate 110. For example, the wafer 100W may be a bulk silicon substrate. Alternatively, the wafer 100W may include an elementary semiconductor, such as silicon (Si) or germanium (Ge) in a crystalline structure; a compound semiconductor, such as silicon germanium (SiGe), silicon carbide (SiC), gallium arsenic (GaAs), gallium phosphide (GaP), indium phosphide (InP), indium arsenide (InAs), and/or indium antimonide (InSb); or combinations thereof. Possible wafer 100W also include a silicon-on-insulator (SOI) substrate. SOI substrates are fabricated using separation by implantation of oxygen (SIMOX), wafer bonding, and/or other suitable methods.

The FEOL process is performed to form FEOL structure 160 on the wafer 100W. In the illustrated embodiments, the FEOL process may include formation of the isolation material 120, the device DE, and the interlayer dielectric layer 162. The isolation material 120 is formed to define at least one active region 112 in the wafer 100W. For example, FIG. 4B shows an active region 112 on which at least one device DE are formed. The isolation material 120 electrically isolates two neighboring active regions 112 from each other. For clear illustration, the chip regions CR of the wafer 100W is illustrated with a region R1 where the main pattern MP is formed and a region R2 where the test structure TS is formed. In some embodiments, functional devices DE, functional circuit pattern, and some dummy circuit patterns are formed over the region R1. The region R2 where the test structure TS is formed may be arranged at one or more suitable positions of the chip CH. For example, in FIG. 4A, there are nine regions R2 in one chip region CR, the region R2 may be located at four corners of the chip region CR, at middles of four sides of the chip region CR, and at a middle of the chip region CR.

The isolation material 120 may be formed within and/or upon wafer 100W by employing methods including but not limited to isolation region thermal growth methods and isolation region deposition/patterning methods. In some embodiments, the isolation material 120 may include a shallow trench isolation (STI) structure, a local oxidation of silicon (LOCOS) structure, other isolation structure, or any combination thereof. In some embodiments, the isolation material 120 is formed, for example, by an STI process, a LOCOS process, or combinations thereof. In some embodiments where the isolation material 120 is formed using STI processes, the formation method includes the steps of etching trenches, and filling the trenches with a filling dielectric material. The filling dielectric material may be silicon oxide, for example.

The device DE may be in the form of transistors, resistors, capacitors, inductors, diodes, circuits, or the like. In some embodiments, the device DE form a static random access memory (SRAM) circuit, an embedded SRAM circuit, dynamic random access memory (DRAM) circuit, an embedded DRAM circuit, a non-volatile memory circuit, e.g., FLASH, EPROM, E2PROME, a field-programmable gate circuit, a digital logic circuit, an analog circuit, a mixed signal circuit, or other circuit.

In some embodiments, each of the devices DE includes a gate structure 130, which includes a gate dielectric 132 and a gate electrode 134 over the gate dielectric 132. The gate dielectric 132 includes a single layer or a multi-layer structure. In some embodiments where the gate dielectric 132 includes a multi-layer structure, the gate dielectric 132 includes an interfacial dielectric layer and a high-k dielectric layer. The interfacial dielectric layer may include a material such as silicon oxide, silicon nitride, silicon oxynitride, other gate dielectric materials, and/or combinations thereof. The interfacial dielectric layer is formed, in one or more embodiments, by thermal processes, CVD processes, ALD processes, epitaxial processes, and/or combinations thereof. The high-k dielectric layer is formed, in some embodiments, over the interfacial layer. The high-k dielectric layer includes high-k dielectric materials such as HfO₂, HfSiO, HfSiON, HfTaO, HfTIO, HfZrO, other suitable high-k dielectric materials, and/or combinations thereof. The high-k material may further be selected from metal oxides, metal nitrides, metal silicates, transition metal-oxides, transition metal-nitrides, transition metal-silicates, oxynitrides of metals, metal aluminates, zirconium silicate, zirconium aluminate, silicon oxide, silicon nitride, silicon oxynitride, zirconium oxide, titanium oxide, aluminum oxide, hafnium dioxide-alumina alloy, other suitable materials, and/or combinations thereof. The high-k dielectric layer may be formed by any suitable process, such as ALD, CVD, PVD, RPCVD, PECVD, MOCVD, sputtering, plating, other suitable processes, and/or combinations thereof.

The gate electrode 134 includes one or more materials including polysilicon, Ti, TiN, TaN, Ta, TaC, TaSiN, W, WN, MON, MOON, RuO₂, and/or other suitable conductive materials. The gate electrodes 134 may include one or more layers formed by physical vapor deposition (PVD), CVD, ALD, plating, and/or other suitable processes. The deposition layer is defined by, e.g., photolithographic process and/or etch process for forming the gate electrodes 134. In some embodiments, the gate electrode 134 further includes a work function metal layer, thereby providing an N-metal work function or P-metal work function of a metal gate. P-type work function materials include compositions such as ruthenium, palladium, platinum, cobalt, nickel, and conductive metal oxides, and/or other suitable materials. N-type metal materials include compositions such as hafnium, zirconium, titanium, tantalum, aluminum, metal carbides (e.g., hafnium carbide, zirconium carbide, titanium carbide, aluminum carbide), aluminides, and/or other suitable materials.

Gate spacers 140 may be formed on opposite sidewalls of the gate structure 130. The gate spacers 140 may include a dielectric material such as silicon oxide, silicon nitride, silicon oxynitride, SiCN films, silicon oxycarbide, SiOCN films, and/or combinations thereof.

Source/drain regions 150 may be formed in the active regions 112 and spaced apart from the gate structure 130 by the gate spacer 140. The source/drain regions 150 may be formed through processes such as ion implantation, thermal diffusion, epitaxial growth, and/or other suitable processes. In some embodiments where the source/drain regions 150 are formed through ion implantation, the source/drain regions 150 may be N-type source/drain regions or p-type source/drain regions. The n-type source/drain regions have dopants such as Arsenic (As), Phosphorus (P), other group V element, or the combinations thereof. The p-type source/drain regions have dopants such as Boron (B) or other group III element. In some embodiments, a thermal process and/or rapid thermal process (RTP) is/are performed after the ion implantation processes. In some embodiments where the source/drain regions 150 are formed through epitaxial growth, a recess may be etched in the wafer 100W at one or more of the source/drain regions. The recess may be etched using suitable etching technology such as dry etching, plasma etching, wet etching, and the like. In some embodiments, the source/drain regions include epitaxial regions formed on and/or above the wafer 100W. In some further embodiments, the epitaxial region may be formed in the etched recess of the wafer 100W.

After the FEOL process, a MEOL process may be performed to form contact plugs CP in the interlayer dielectric layer 162. Formation of the contact plugs CP may include etching holes in the interlayer dielectric layer 162 to expose the source/drain regions 150 and the gate electrode 134 and filling the holes with a suitable conductive material, such as tungsten. A chemical mechanical polishing (CMP) process may be performed to remove an excess portion of the conductive material, and remaining portions of the conductive material form the contact plugs CP.

After the formation of the contact plugs CP in the MEOL process, a BEOL process is performed to form a BEOL structure 170 over the contact plugs CP. The BEOL process may include the formation of the metallization layers and the via layers. The formation of each of the metallization and/or via layers may include depositing a dielectric layer, etching vias and/or trenches in the dielectric layer, filling the vias and/or trenches in the dielectric layer with a metal material, and removing an excess portion of the metal material from the vias and/or trenches. Thus, the formed BEOL structure 170 includes plural stacked metallization layers and via layers embedded in the one or more dielectric layers 174. In the illustrated embodiments, the BEOL structure 170 includes metal layers M0-M17 and the vertical columnar vias V0-V16. The number of the metal layers and the vertical columnar vias may vary in some other embodiments.

In some embodiments, a portion of the metallization layers and the via layers of BEOL structure 170 in the region R1 may form a main pattern MP electrically connected with the device DE of the FEOL structure 160. In FIG. 4B, the metal lines 172M of every two adjacent metallization layers of the main pattern MP may extend along two different directions, respectively. For example, while the metallization layers are stacked vertically along the direction z, the metal lines 172M of the even-numbered metallization layers M0, M2, M4, M6, M8, M10, M12, M14, and M16 extend substantially along the direction X, while the metal lines 172M of the odd-numbered metallization layers M1, M3, M5, M7, M9, M11, M13, M15, and M17 extend substantially along the direction Y, in which the direction X, Y, Z are orthogonal to each other.

On the other hand, a portion of the metallization layers and the via layers of BEOL structure 170 in the region R2 may form the test structure TS, electrically isolated from the device DE of the FEOL structure 160. In FIG. 4B, the metal lines 172M of the metallization layers of the main pattern MP may extend substantially along the same direction. For example, while the metallization layers are stacked vertically along the direction Z, both the metal lines 172M of the even-numbered metallization layers M0, M2, M4, M6, M8, M10, M12, M14, and M16 and the metal lines 172M of the odd-numbered metallization layers M1, M3, M5, M7, M9, M11, M13, M15, and M17 extend substantially along the direction X. Stated differently, each of the odd-numbered metallization layers M1, M3, M5, M7, M9, M11, M13, M15, and M17 may have some metal lines 172M extending along the direction Y for the main pattern MP and some metal lines 172M extending along the direction X for the test structure TS.

Contact pads 182, 184, and 186 are formed over the BEOL structure 170. The contact pads 182, 184, and 186 may comprise copper, aluminum, or another conductive material. In some embodiments, the contact pads 182, 184, and 186 may comprise conductive pillars having a solder cap disposed thereon. In some embodiments, a conductive connector may be optionally formed on the contact pads 182, 184, and 186. The contact pads 186 may be electrically connected with the main pattern MP. As aforementioned, the contact pads 182 and 184 are test pads electrically connected with the test structure TS. A passivation layer PL may be coated over the contact pads 182, 184, and 186 and patterned, for example, by photolithography process, to expose the contact pads 182, 184, and 186. The passivation layer PL may include suitable photo-sensitive material such as PBO, polyimide, BCB, or the like, which may be patterned using a lithography mask.

Subsequently, die connectors 190, such as conductive pillars (formed of a metal such as copper, for example), extend through the openings in the passivation layer PL and are physically and electrically coupled to respective ones of the exposed contact pads 182, 184, and 186. The die connectors 190 may be formed by, for example, plating, or the like. The die connectors 190 electrically couple the respective integrated circuits of the active chip regions CR and the test structure TS.

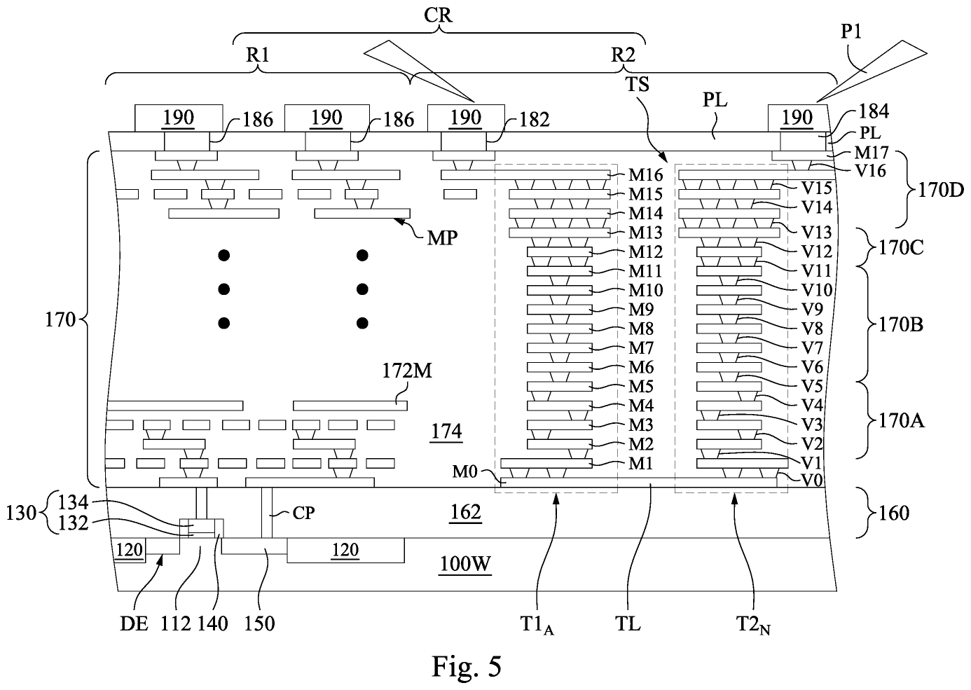

Reference is made to FIG. 3 and FIG. 5. The method M proceeds to step S2, where an EOS test is performed on chip regions CR of the wafer 100W. For example, a chip probe test may be applied to the die connectors 190 over the contact pads 182 and 184 of the chip regions CR of the wafer 100W. For example, the probes P1 are in contact with the die connectors 190. The chip probe test checks electrical functionality of the chip regions CR. For example, a current flow from a die connector 190 over the contact pad 182 to a die connector 190 over the contact pad 184 through the test structure TS is measured. Stated differently, a resistance between the die connectors 190 respectively over the contact pad 182 and the contact pad 184 is detected by the chip probe test. In some embodiments, the process for fabricating the wafer may induce a large number of electrostatic charges in the wafer, which may induce EOS burn out in the test structure TS. A burned-out test structure may short the test structure TS. By the chip probe test, a current flow through the test structure TS or a resistance of the test structure can be measured, in which a low current or a high resistance indicates the test structure TS does not burn out, and a high current or a low resistance (or a short circuit) indicates the test structure TS has burned out. By the chip probe test, the wafer 100W is under a die hot zone identification process, thereby creating a map of hot zones of the wafer 100W. The map of hot zones of the wafer 100W may indicate a weak point in the fabrication process (e.g., the FEOL process or the BEOL process), and a maintaining operation may be performed for adjusting various process parameters of the fabrication process to address the weak point of the fabrication process. For example, once the test results show the number of the burned-out chip regions CR is higher than a threshold number, it is determined that the fabrication process (e.g., the BEOL process) has issues, and a maintaining operation should be performed for adjusting various process parameters of the fabrication process to address the issues of the fabrication process.

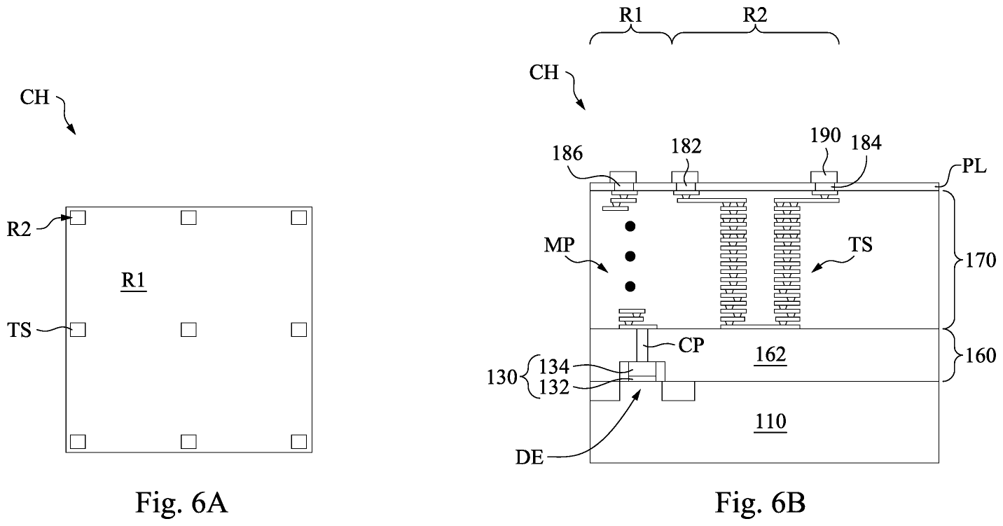

Reference is made to FIG. 3. The method M proceeds to step S3, where a singulation process is performed to separate the chip regions CR of the wafer 100W. The singulation process may include mechanical sawing, laser dicing, plasma dicing, combinations thereof, or the like. For example, the singulation process may be performed on the scribe line regions SR. After the singulation process, the chip regions CR of the wafer 100W are referred to as dies or chips CH. An example individual chip CH is shown as FIGS. 6A and 6B.

FIG. 6A is a top view of the individual chip CH according to some embodiments of the present disclosure. FIG. 6B is a cross-sectional view of the individual chip CH of FIG. 6A. The chip CH may include the region R1 where the main pattern MP (referring to FIG. 4B) is formed and the region R2 where the test structure TS is formed. The region R2 where the test structure TS is formed may be arranged at one or more suitable positions of the chip CH. For example, in FIG. 6A, the region R2 may be located at four corners of the individual chip CH, at middles of four sides of the individual chip CH, and at a middle of the individual chip CH. After the singulation process, the wafer 100W (referring to FIG. 4B) may be referred to as a substrate 110.

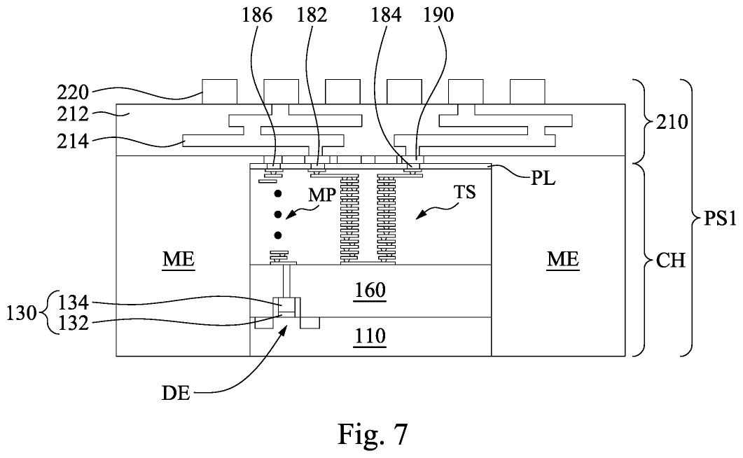

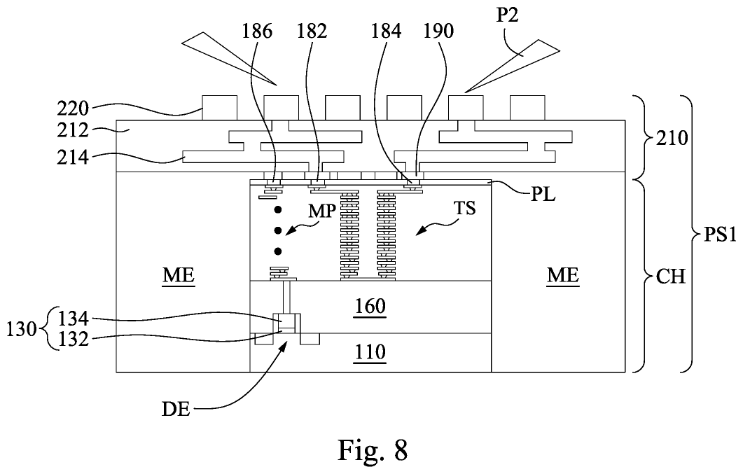

Reference is made to FIG. 3 and FIG. 7. The method M proceeds to step S4, where a redistribution structure 210 is formed over the chip CH to form a first package structure PS1. The redistribution structure 210 includes dielectric layers 212 and metallization patterns 214. The metallization patterns 214 may also be referred to as redistribution layers or redistribution lines. The redistribution structure 210 illustrated in FIG. 8 includes three layers of metallization patterns; however, more or fewer metallization patterns may be included in the redistribution structure 210. In some embodiments, the dielectric layers 212 are formed of a photo-sensitive material such as PBO, polyimide, BCB, or the like, which may be patterned using a lithography mask. The metallization pattern 214 includes line portions (also referred to as conductive lines) on and extending along the major surface of the dielectric layers 212. The metallization pattern 214 further includes via portions (also referred to as conductive vias) extending through the dielectric layers 212 to physically and electrically couple the underlying conductive features.

In some embodiments, prior to the formation of the redistribution structure 210, an encapsulant ME is formed to laterally encapsulate the chip CH. The encapsulant ME may include a molding compound, a molding underfill, a resin such as epoxy, a combination thereof, or the like. In some other embodiments, the encapsulant ME includes a polymer material such as polybenzoxazole (PBO), polyimide (PI), benzocyclobutene (BCB), a combination thereof, or the like. In alternative embodiments, the encapsulant ME may include inorganic dielectric material. For example, the encapsulant ME may include nitride such as silicon nitride, oxide such as silicon oxide, phosphosilicate glass (PSG), borosilicate glass (BSG), boron-doped phosphosilicate glass (BPSG), a combination thereof, or the like. In some embodiments, the encapsulant ME includes a molding compound, and may be formed by an over-molding process and a planarization process. For example, an encapsulant material layer is formed over the carrier to encapsulate sidewalls and the top surface (i.e. front surface) of the chip CH through an over-molding process. Thereafter, a planarization process such as a chemical mechanical polishing (CMP) process is performed to remove a portion of the encapsulant material layer over the front surface of the chip CH to expose the die connectors 190, and the encapsulant ME is formed. And, the redistribution structure 210 may be formed over the encapsulant ME and the chip CH.

Conductive features 220 are formed for external connection to the redistribution structure 210. The conductive features 220 may include suitable conductive connectors, such as bumps, contact pads, solders, the like, or the combination thereof. In some embodiments, the conductive features 220 may include under-bump metallization (UBMs) electrically connected with the metallization patterns 414, in which the conductive connectors 420 may be located below the conductive connectors. In some embodiments, the conductive features 220 may have bump portions on and extending along a major surface of the dielectric layer 212, and have via portions extending through the dielectric layer 212 to physically and electrically couple to the metallization pattern 214. As a result, the conductive features 220 are electrically coupled to the test structure TS, the main pattern MP, and the devices DE. The conductive features 220 may be formed of the same material as the metallization pattern 214. In some embodiments, the conductive features 220 may have different sizes from the metallization patterns 214.

Reference is made to FIG. 3 and FIG. 8. At step S5, an EOS test is performed on the first package structure PS1. For example, a chip probe test may be applied to the conductive features 220 that is electrically connected to the contact pads 182 and 184 of the chip CH. For example, the probes P2 are in contact with the conductive features 220. The chip probe test checks electrical functionality of the chips CH after the formation of the redistribution structure 210. For example, a current flow through the test structure TS from a conductive feature 220 electrically connected with the contact pad 182 to a conductive feature 220 electrically connected with the contact pad 184 is measured. Stated differently, a resistance between the two conductive features 220 is detected by the chip probe test. In some embodiments, the process for fabricating the chips and the redistribution structure 210 may induce a large number of electrostatic charges in the chips, which may induce EOS burn out in the test structure TS. A burned-out test structure may short the test structure TS. By the chip probe test, a current flow through the test structure TS or a resistance of the test structure can be measured, in which a low current or a high resistance indicates the test structure TS does not burn out, and a high current or a low resistance (or a short circuit) indicates the test structure TS has burned out. Results of the chip probe test may indicate a weak point in the fabrication process (e.g., the formation of the redistribution structure 210), and a maintaining operation may be performed for adjusting various process parameters of the fabrication process to address the weak point of the fabrication process. The first package structure PS1 that do not pass the chip probe tests are discarded or repaired. The first package structure PS1 that passes the chip probe tests are provided for packaging, which reduces waste and expense of packaging.

In some embodiments, after the EOS test of step S5, some components may be formed/mounted on the first package structure PS1, and then an EOS test is performed on the first package structure PS1. For example, the components may include some lead, cover material, dynamic random access memory (DRAM), the like, or the combination thereof. For example, a chip probe test may be applied to the conductive features 220 that is electrically connected to the contact pads 182 and 184 of the chip CH. For example, the probes P2 are in contact with the conductive features 220. The chip probe test checks electrical functionality of the chips CH after the formation or mounting of the components on the first package structure PS1. Results of the chip probe test may indicate a weak point in the fabrication process (e.g., the formation of the components), and a maintaining operation may be performed for adjusting various process parameters of the fabrication process to address the weak point of the fabrication process. In context, both the EOS test before and after the formation or mounting of the components on the first package structure PS1 may be referred to as a wafer-level chip probe test, in which the EOS test before the formation or mounting of the components on the first package structure PS1 may be referred to as first final test, and the EOS test before the formation or mounting of the components on the first package structure PS1 may be referred to as second final test.

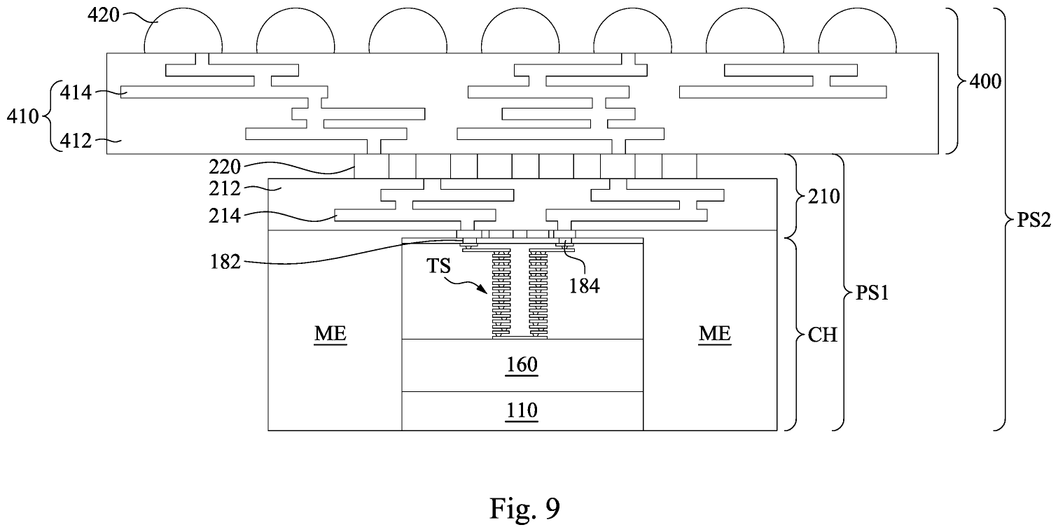

Reference is made to FIG. 3 and FIG. 9. At step S6, the first package structure PS1 is bonded with a package substrate 400 to form a second package structure PS2. The first package structure PS1 may be placed over the package substrate 400 using a pick and place machine or the like. Once the first package structure PS1 is placed, the conductive connectors over the conductive features 220 may be reflowed to bond the first package structure PS1 to the package substrate 400.

In some embodiments, the package substrate 400 may be a printed circuit board (PCB). In some other embodiments, the package substrate may be a silicon interposer. In some embodiments, the package substrate 400 may include a redistribution structure 410 including dielectric layers 412 and metallization patterns 414. The metallization patterns may also be referred to as redistribution layers or redistribution lines. The redistribution structure 410 is shown as an example having four layers of metallization patterns. More or fewer metallization patterns may be formed in the redistribution structure 410.

Conductive connectors 420 are formed on the redistribution structure 410. The conductive connectors 420 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 420 may include a conductive material such as solder, copper, aluminum, gold, nickel, silver, palladium, tin, the like, or a combination thereof. In some embodiments, the conductive connectors 420 are formed by initially forming a layer of solder through such commonly used methods such as evaporation, electroplating, printing, solder transfer, ball placement, or the like. Once a layer of solder has been formed on the structure, a reflow may be performed in order to shape the material into the desired bump shapes.

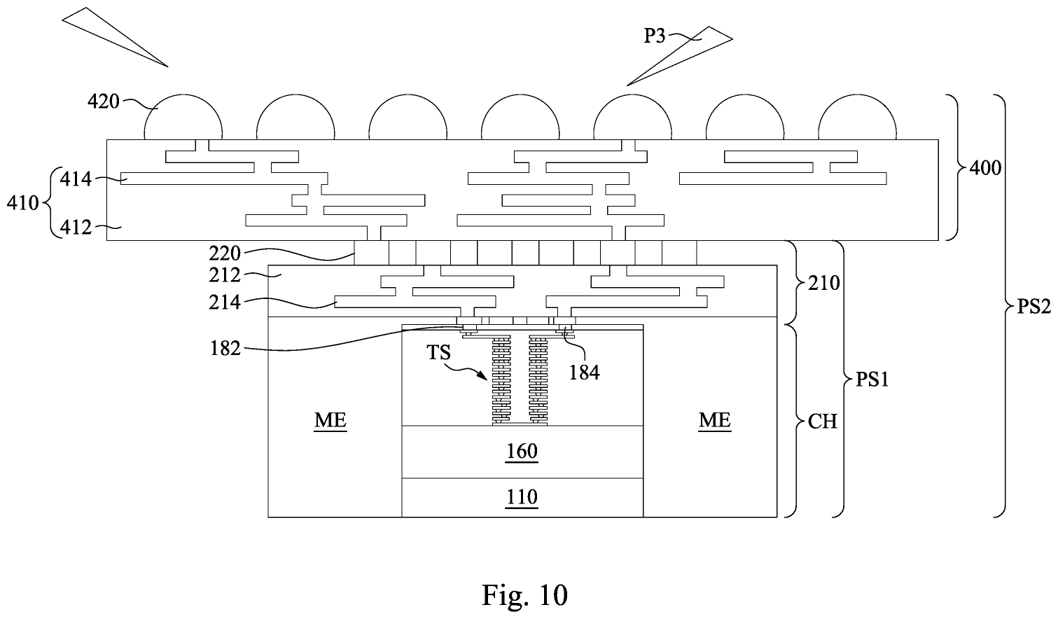

Reference is made to FIG. 3 and FIG. 10. At step S7, an EOS test is performed on the second package structure PS2. For example, a chip probe test may be applied to the conductive connectors 420 that is electrically connected to the contact pads 182 and 184 of the chip CH. The EOS test may also be referred to as a system-level test. For example, the probes P3 are in contact with the conductive connectors 420. The chip probe test checks electrical functionality of the chips CH after the bonding process with the package substrate 400. For example, a current flow through the test structure TS from a conductive connector 420 electrically connected with the contact pad 182 to another conductive connector 420 electrically connected with the contact pad 184 is measured. Stated differently, a resistance between the two conductive connectors 420 is detected by the chip probe test. In some embodiments, the bonding process with the package substrate 400 may induce a large number of electrostatic charges in the chips, which may induce EOS burn out in the test structure TS. A burned-out test structure may short the test structure TS. By the chip probe test, a current flow through the test structure TS or a resistance of the test structure can be measured, in which a low current or high resistance indicates the test structure TS does not burn out, and a high current or a low resistance (or a short circuit) indicates the test structure TS has burned out. Results of the chip probe test may indicate a weak point in the fabrication process (e.g., the bonding with the package substrate 400), and a maintaining operation may be performed for adjusting various process parameters of the fabrication process to address the weak point of the fabrication process. The second package structure PS2 that do not pass the chip probe tests are discarded or repaired. The second package structure PS2 that passes the chip probe tests are provided for packaging, which reduces waste and expense of packaging.

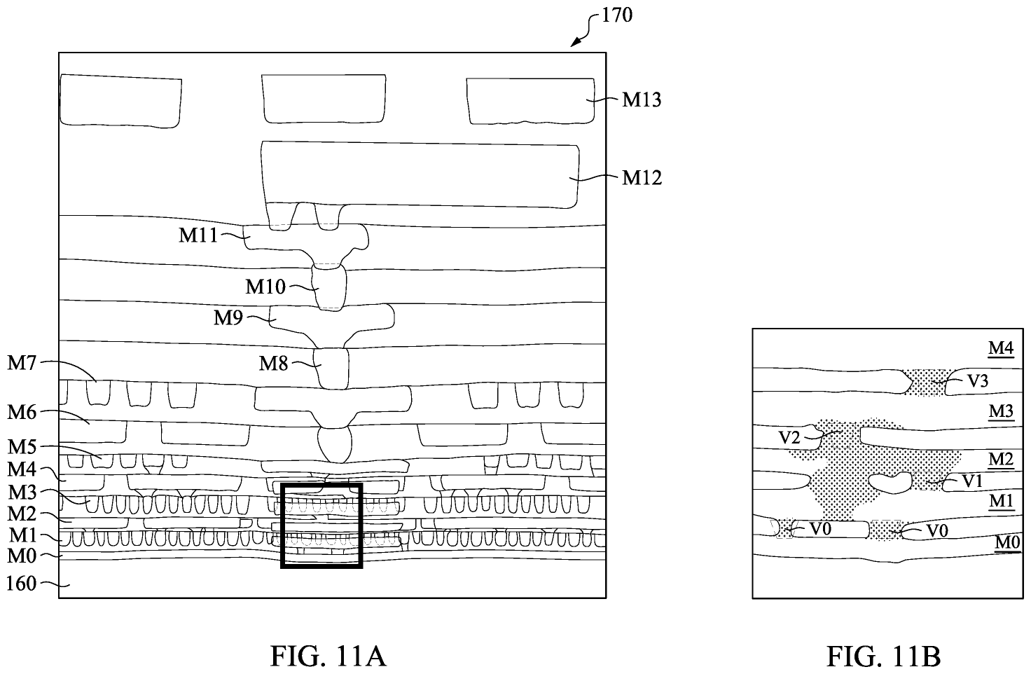

FIG. 11A is a cross-sectional view illustrating a test structure with burn-out according to some embodiments of the present disclosure. FIG. 11B is an enlarged view of a portion of FIG. 11A. It is evidenced that an event of EOS burn out occurs in the test structure TS. For example, the dotted pattern in FIG. 11B indicates the burn-out regions. The burned-out device can be simply and quickly detected under the chip probe test. By using the test structure TS, the number of failing dies increases, and the yield loss increases, which indicates that the test structure TS offers a good EOS detectability and improved EOS sensitivity.

Based on the above discussions, it can be seen that the present disclosure offers advantages over semiconductor devices. It is understood, however, that other embodiments may offer additional advantages, and not all advantages are necessarily disclosed herein, and that no particular advantage is required for all embodiments. One advantage is that a resistor-like structure in BEOL layers is designed as a test pattern monitoring EOS (electrostatic over stress), and the resistor-like test structure has a small footprint and good EOS sensitivity. Another advantage is that this resistor-like structure can detect EOS risk in die level, package level, and system level within chip probe test, wafer-level chip probe test, and final test. Still another advantage is that the resistor-like structure can be tested in chip probe test, wafer-level chip probe test, and final test to monitor top die, Integrated Fan-out (InFO), on-substrate process loops. Still another advantage is that the resistor-like structure in BEOL layers can be applied in SoC packaged by flip-chip, Chip on Wafer on Substrate (CoWoS), and Integrated Fan-out (InFO) family test vehicle.

According to some embodiments of the present disclosure, a method for fabricating a semiconductor device is provided. The method includes forming a transistor over a semiconductor substrate; forming an interconnect structure over the transistor, forming a first conductive pad and a second conductive pad over the interconnect structure, and performing a first probe test on the first conductive pad and the second conductive pad. The interconnect structure includes a first via layer; a first metallization layer over the first via layer; a second via layer over the first metallization layer; a second metallization layer over the second via layer; and a third via layer over the second metallization layer. The interconnect structure comprises a test structure, the test structure comprises a first node, a second node, and at least one tower connected between the first node and the second node. The at least one tower of the test structure comprises at least one test metal via of the first via layer, at least one test metal via of the second via layer, and at least one test metal via of the third via layer. A size of the at least one test metal via of the second via layer is less than a size of the at least one test metal via of the third via layer, and a number of the at least one test metal via of the second via layer is less than a number of the at least one test metal via of the first via layer. The first conductive pad and the second conductive pad are respectively electrically connected with the first and second nodes of the test structure.

According to some embodiments of the present disclosure, a method for fabricating a semiconductor device is provided. The method includes forming a transistor over a semiconductor substrate; forming an interconnect structure over the transistor, and performing a first probe test by directing a current through the test structure. The interconnect structure comprises a test structure. The test structure comprising: a first metal line; a plurality of second metal lines vertically arranged above the first metal line and spaced apart from each other; a third metal line above the second metal lines; two first metal via connecting the first metal line to a bottommost one of the second metal lines; a second metal via connecting a first one of the second metal lines to a second one of the second metal lines; and two third metal via connecting a topmost one of the second metal lines to the third metal line.

According to some embodiments of the present disclosure, a semiconductor device includes a semiconductor substrate, wherein the semiconductor substrate has a device region and a test region at a side of the device region; a transistor over the device region of the semiconductor substrate; an interconnect structure over the semiconductor substrate. The interconnect structure includes a first via layer; a first metallization layer over the first via layer; a second via layer over the first metallization layer; a second metallization layer over the second via layer; and a third via layer over the second metallization layer. The interconnect structure has a test structure over the test region, at least one tower of the test structure comprises at least one test metal via of the first via layer, at least one test metal via of the second via layer, and at least one test metal via of the third via layer. A size of the at least one test metal via of the second via layer is less than a size of the at least one test metal via of the third via layer, and a number of the at least one test metal via of the second via layer is less than a number of the at least one test metal via of the first via layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for fabricating a semiconductor device, comprising:
forming a transistor over a semiconductor substrate;
forming an interconnect structure over the transistor, wherein the interconnect structure comprises:
a first via layer;
a first metallization layer over the first via layer;
a second via layer over the first metallization layer;
a second metallization layer over the second via layer; and
a third via layer over the second metallization layer, wherein the interconnect structure comprises a test structure, the test structure comprises a first node, a second node, and at least one tower connected between the first node and the second node, the at least one tower of the test structure comprises at least one test metal via of the first via layer, at least one test metal via of the second via layer, and at least one test metal via of the third via layer, a size of the at least one test metal via of the second via layer is less than a size of the at least one test metal via of the third via layer, and a number of the at least one test metal via of the second via layer is less than a number of the at least one test metal via of the first via layer;
forming a first conductive pad and a second conductive pad over the interconnect structure, wherein the first conductive pad and the second conductive pad are respectively electrically connected with the first and second nodes of the test structure; and
performing a first probe test on the first conductive pad and the second conductive pad.

2. The method of claim 1, wherein forming the interconnect structure is performed such that the number of the at least one test metal via of the second via layer is less than a number of the at least one test metal via of the third via layer.

3. The method of claim 1, wherein forming the interconnect structure is performed such that the test structure is electrically isolated from the transistor.

4. The method of claim 1, further comprising:
after the first probe test, separating the semiconductor substrate into a plurality of chips.

5. The method of claim 1, further comprising:
after the first probe test, forming a redistribution structure over the interconnect structure, wherein the redistribution structure comprises first and second conductive features are respectively electrically connected with the first conductive pad and the second conductive pad.

6. The method of claim 5, further comprising:
performing a second probe test on the first and second conductive features of the redistribution structure.

7. The method of claim 5, further comprising:
bonding the semiconductor substrate to a package substrate, wherein the package substrate comprises first and second conductive features are respectively electrically connected with the first and second conductive features of the redistribution structure.

8. The method of claim 7, further comprising:
performing a third probe test on the first and second conductive features of the package substrate.

9. A method for fabricating a semiconductor device, comprising:
forming a transistor over a semiconductor substrate;
forming an interconnect structure over the transistor, wherein the interconnect structure comprises a test structure, the test structure comprising:
a first metal line;
a plurality of second metal lines vertically arranged above the first metal line and spaced apart from each other;
a third metal line above the second metal lines;
two first metal via connecting the first metal line to a bottommost one of the second metal lines;
a second metal via connecting a first one of the second metal lines to a second one of the second metal lines; and
two third metal via connecting a topmost one of the second metal lines to the third metal line; and
performing a first probe test by directing a current through the test structure.

10. The method of claim 9, wherein a size of the second metal via is less than a size of the third metal vias.

11. The method of claim 9, wherein a size of the first metal vias is less than or equal to a size of the second metal via.

12. The method of claim 9, wherein forming the interconnect structure is performed such that an entirety of a bottom surface of the first one of the second metal lines is in contact with the second metal via and a dielectric layer surrounding the second metal via.

13. A semiconductor device, comprising:
a semiconductor substrate, wherein the semiconductor substrate has a device region and a test region at a side of the device region;
a transistor over the device region of the semiconductor substrate; and
an interconnect structure over the semiconductor substrate, wherein the interconnect structure comprises:
a first via layer;
a first metallization layer over the first via layer;
a second via layer over the first metallization layer;
a second metallization layer over the second via layer; and
a third via layer over the second metallization layer, wherein the interconnect structure has a test structure over the test region, at least one tower of the test structure comprises at least one test metal via of the first via layer, at least one test metal via of the second via layer, and at least one test metal via of the third via layer, a size of the at least one test metal via of the second via layer is less than a size of the at least one test metal via of the third via layer, and a number of the at least one test metal via of the second via layer is less than a number of the at least one test metal via of the first via layer.

14. The semiconductor device of claim 13, wherein a height of the at least one test metal vias of the third via layer is greater than a height of the at least one test metal via of the second via layer.

15. The semiconductor device of claim 13, wherein the number of the at least one test metal via of the second via layer is less than a number of the at least one test metal via of the third via layer.

16. The semiconductor device of claim 13, wherein a height of the at least one test metal via of the second via layer is substantially the same as a height of the at least one test metal via of the first via layer.

17. The semiconductor device of claim 13, wherein a thickness of the second metallization layer is greater than a thickness of the first metallization layer.

18. The semiconductor device of claim 13, wherein the at least one test metal via of the first via layer is misaligned with the at least one test metal via of the second via layer in a vertical direction.

19. The semiconductor device of claim 13, further comprises:
a first conductive pad and a second conductive pad over the interconnect structure, wherein the test structure electrically connects the first conductive pad to the second conductive pad.

20. The semiconductor device of claim 13, wherein the test structure comprises a connection line of the first metallization layer connecting two of the test towers to each other.
